(19) United States
(12) Patent Application Publication
(10) Pub. No.: US 2005/0027470 A1
(43) Pub. Date: Feb. 3, 2005

(54) Interactive stub apparatus for testing a program and stub program storage medium

(75) Inventors: Masaki Tonomura, Kawasaki (JP); Hayato Hamamoto, Osaka (JP); Junichi Nakagaki, Osaka (JP)

Correspondence Address: STAAS & HALSEY LLP, SUITE 700, 1201 NEW YORK AVENUE, N.W., WASHINGTON, DC, 20005, US

(73) Assignee: FUJITSU LIMITED, Kawasaki (JP)

(21) Appl. No.: 10/784,983

(22) Filed: Feb. 25, 2004

(30) Foreign Application Priority Data
Jul. 17, 2003 (JP) 2003-198251

(51) Int. Cl. G01R 31/00

(52) U.S. Cl. 702/120

(57) ABSTRACT

For the purpose of eliminating the need for creating a stub program dedicated to a program to be tested and for setting a test environment, and of increasing the efficiency of test operations, an electronic text parsing unit parsing an electronic text transmitted externally from a program to be tested to detect a required data item, and an electronic text data setting unit embedding an input data value, which corresponds to the detected data item, in an electronic text to be transmitted to a side of the program to be tested are comprised to test the program for executing a process with externally given data.

### BACKGROUND OF THE INVENTION

1. Field of the Invention

The present invention relates to a program test method, and more particularly, to an interactive stub apparatus for testing a program on a client side if a program on a server side is not completed when a client/server system is developed.

2. Description of the Related Art

For example, in a test of some modules in a program configured by a plurality of modules, or in a test of a program reading an external program and using its process result, it is desirable to test a module to be tested or a program to be tested after all of the modules or the external program is completed.

Generally, however, a test of a module unit or a test program unit must be run. For example, in the development of a client/server system, a test of a program on the client side cannot be run despite its completion unless a program on the server side is completed. A conventional method testing a program on a client side in such a case is described with reference to FIGS. 1 and 2.

In FIG. 1, a server reading process on a client program side is invalidated, and a test is run after data 1 as a virtual server process result is embedded in a program source, which is then compiled. According to a result of the test, a modification for changing the data 1 embedded in the source to data 2 is made. Then, the source is again tested after being compiled. The client program is tested by repeating such a test.

In FIG. 2, a stub program (source) for testing a client program is created, and a test is run after a source of a client program is modified to call the stub program from the source of the client program and compiled, and data 1 is created and stored in a file. Data 2 is created according to a result of the test, and the test is repeated with a file of the data 2.

The following documents exist as a conventional technique of such a method running a program unit test.

Document 1 discloses a program unit test method replacing an external program to be called with a single stub program having a high function, returning control to the program to be tested after performing a predefined operation in a pseudo manner in the stub program, and outputting a result of the program.

Document 2 discloses a test aiding tool detecting the existence of a high-order or a low-order module in a module test of a program configured by a plurality of modules, and executing a substitute function for a module depending on whether an existing module is either high-order or low-order.

[Document 1]

Japanese Patent Application Publication No. SHO63-201738 “Program Unit Test Method”

[Document 2]

Japanese Patent Publication No. HEI6-19731 “Program Unit Test Method”

However, such conventional techniques have a problem that a program source must be modified each time given data is changed, or a lot of trouble is taken to create a dedicated stub program. The conventional techniques also have a problem that operation definition information, test data, etc. on a stub program side must be set prior to a test, and a test environment must be set each time a test is run, even if a shared stub program is created.

### SUMMARY OF THE INVENTION

An object of the present invention is to provide an interactive stub apparatus for testing a program, which parses an electronic text transmitted from a test program to an external program side to detect an item for which a data value setting is required, and creates a stub program dedicated to the test program and eliminates the need for setting a test environment, for example, by making a user set the value, in order to overcome the above described problems.

The interactive stub apparatus for testing a program according to the present invention is an apparatus for testing a program for executing a process with externally given data, and comprises at least an electronic text parsing unit and an electronic text data setting unit.

The electronic text parsing unit parses an electronic text transmitted from a program to be tested to detect a required data item. The electronic text data setting unit embeds an input data value, which corresponds to the data item detected by the electronic text parsing unit, in an electronic text to be transmitted to a side of the program to be tested.

A computer-readable portable storage medium according to the present invention, on which is recorded a stub program for causing a computer to execute a process, the process comprising: parsing an electronic text transmitted from a program to be tested to detect a required data item; and embedding an input data value, which corresponds to the detected data item, in an electronic text to be transmitted to a side of the program to be tested.

A program test method according to the present invention is a method testing a program for executing a process with externally given data, and comprises: parsing an electronic text transmitted from a program to be tested to detect a required data item; and embedding an input data value, which corresponds to the detected data item, in an electronic text to be transmitted to a side of the program to be tested.

As described above, according to the present invention, the need for creating a stub program which corresponds to a program each time a test is run is eliminated by embedding an input data value, which corresponds to a data item required on a side of the program to be tested, in an electronic text to be transmitted to the side of the program to be tested.

### BRIEF DESCRIPTION OF THE DRAWINGS

FIG. 1 explains a conventional example (No. 1) of a program test method;

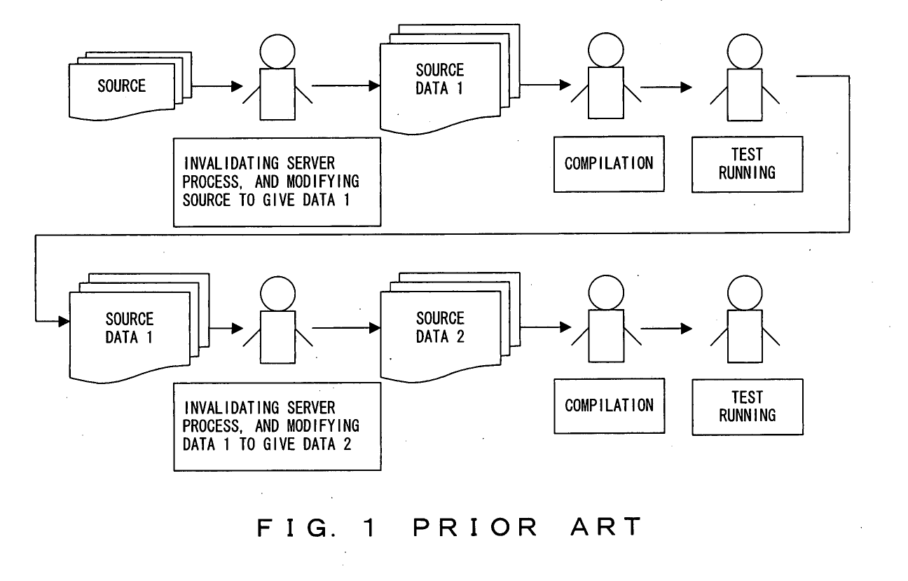

FIG. 2 explains a conventional example (No. 2) of a program test method;

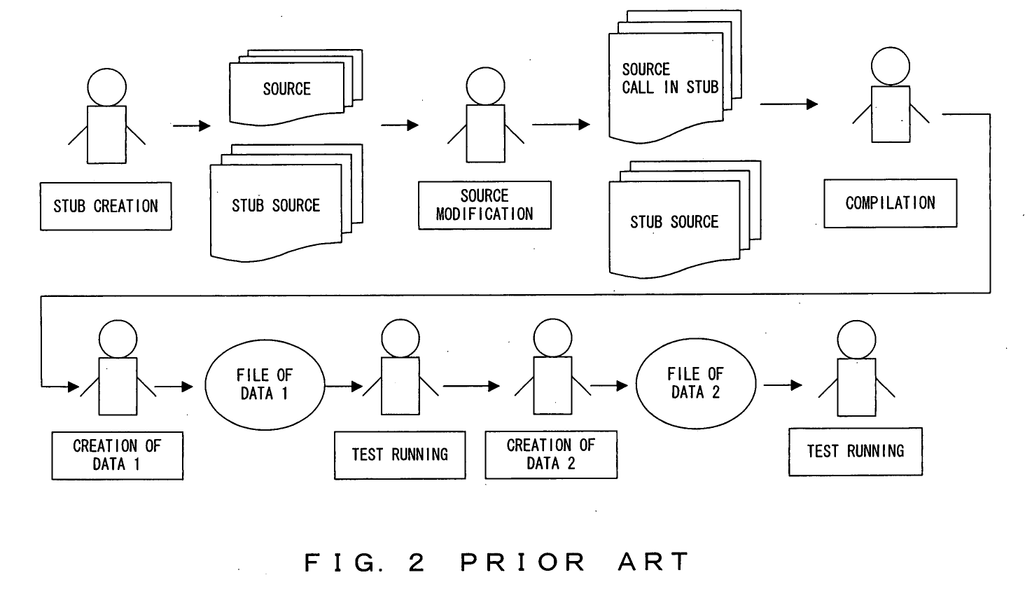

FIG. 3 is a block diagram showing the principle configuration of an interactive stub apparatus for testing a program according to the present invention;

FIG. 4 explains basic program test procedures in a preferred embodiment;

FIG. 5 is a block diagram showing the configuration of a general-purpose interactive stub apparatus;

FIG. 6 explains the whole of a program test method using the general-purpose interactive stub apparatus;

FIG. 7 explains a user view of the general-purpose interactive stub apparatus;

FIG. 8 is a flowchart showing a process executed by an electronic text structure parsing function;

FIG. 9 is a flowchart showing a process executed by a setting screen generating function;

FIG. 10 is a flowchart showing a process executed by an input value generating function;

FIG. 11 is a flowchart showing a process executed by an electronic text data setting/storing function;

FIG. 12 is a flowchart showing a process executed by an electronic text data reading function;

FIG. 13 explains a description example of a general-purpose interactive stub apparatus call;

FIG. 14 explains an example (No. 1) of electronic text parsing made by the electronic text structure parsing function;

FIG. 15 explains an example (No. 2) of electronic text parsing made by the electronic text structure parsing function;

FIG. 16 explains an example of operations of the electronic text structure parsing function and the input value generating function;

FIG. 17 explains an example of operations of the setting screen generating function;

FIG. 18 explains an example of operations of the electronic text data setting/storing function;

FIG. 19 explains an example of operations of the electronic text data reading function; and

FIG. 20 explains the loading of a program in a preferred embodiment into a computer.

### DESCRIPTION OF THE PREFERRED EMBODIMENTS

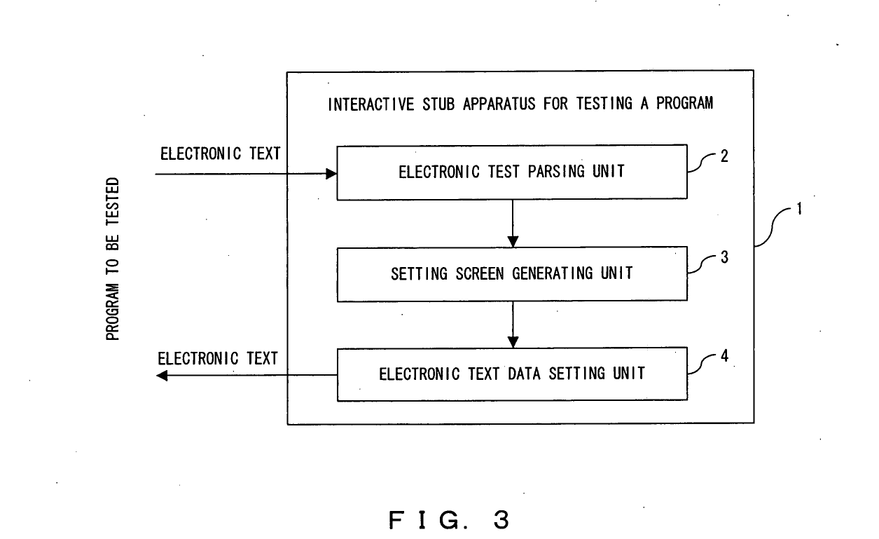

FIG. 3 is a block diagram showing the principle configuration of an interactive stub apparatus for testing a program according to the present invention. In this figure, the stub apparatus 1 comprises at least an electronic text parsing unit 2 and an electronic text data setting unit 4.

The stub apparatus 1 tests a program to be tested for executing a process with externally given data, normally, data given from an external program side. The electronic text parsing unit 2 parses an electronic text transmitted from the program to be tested to an external side, namely, the stub apparatus 1 to detect a required data item. The electronic text data setting unit 4 embeds an input data value, which corresponds to the detected data item, in an electronic text to be transmitted to a side of the program to be tested.

In a preferred embodiment of the present invention, the interactive stub apparatus for testing a program 1 can also comprise a setting screen generating unit 3. The setting screen generating unit 3 generates a data setting screen for receiving from a user the input data value, which corresponds to the data item detected by the electronic text parsing unit 2, and gives a value set, for example, by the user to the electronic text data setting unit 4.

Additionally, in the preferred embodiment, the stub apparatus 1 can further comprise an input value generating unit, not shown, automatically generating input data, which corresponds to the data item detected by the electronic text parsing unit 2, and giving the generated input data to the setting screen generating unit, or can further comprise an electronic text data storing unit storing the set data value, which is embedded by the electronic text data setting unit 4, and an electronic text data reading unit reading stored data, and giving the read data to the setting screen generating unit 3 as input data.

A storage medium according to the present invention is a portable storage medium, which is used by a computer for testing a program to be tested for executing a process with externally given data, and on which is stored a program for causing the computer to execute a process, the process comprising: a step of parsing an electronic text transmitted from a program to be tested to detect a required data item; and a step of embedding an input data value, which corresponds to the detected data item, in an electronic text to be transmitted to a side of the program to be tested.

As described above, according to the present invention, on a screen of the interactive stub apparatus for testing a program, data is set, for example, from a user, and the set data is transmitted to a side of a program to be tested, so that the program is tested.

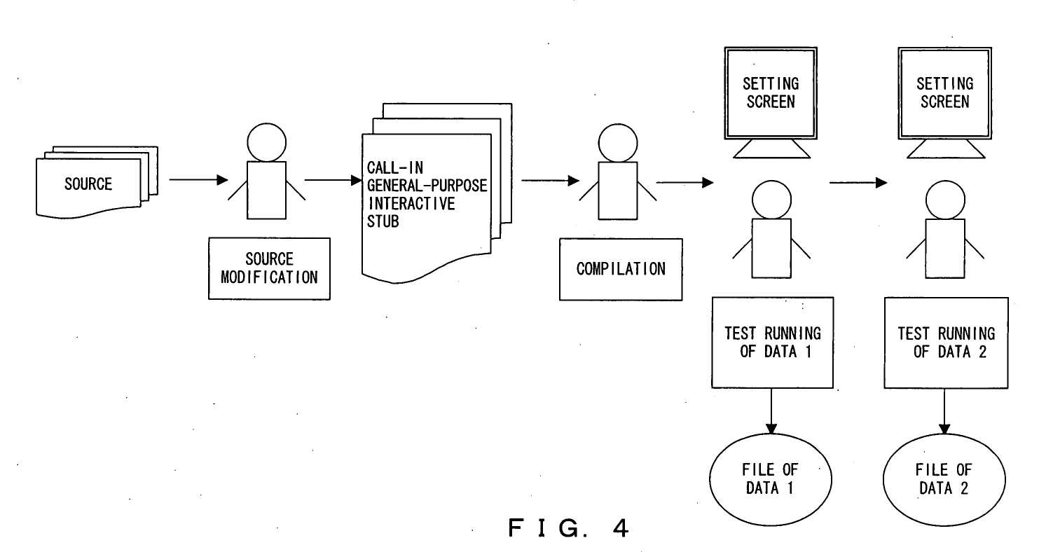

FIG. 4 explains the basic operations of a program testing method according to the present invention. In this figure, a program to be tested, for example, a source of a client program is modified to call a general-purpose interactive stub apparatus in the source and compiled, and required data is set, for example, by a user on a setting screen of the general-purpose interactive stub apparatus, so that the test is run, the data is changed in correspondence with a result of the data, and the test is again run.

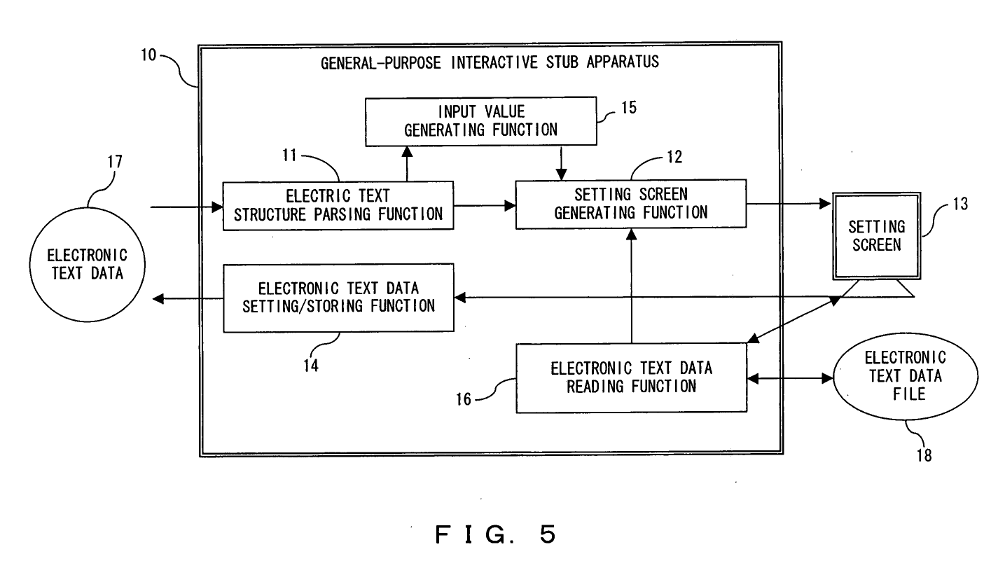

FIG. 5 is a block diagram showing the basic configuration of the general-purpose interactive stub apparatus according to a preferred embodiment. In this figure, the general-purpose interactive stub apparatus 10 comprises: an electronic text structure parsing function 11 parsing electronic text data 17 transmitted from a client program side to detect a data item for which a data input is required; a setting screen generating function 12 generating a setting screen on which a data input is made, for example, by a user for the item for which the data input is required; an electronic text data setting/storing function 14 setting the data, which is input on the setting screen 13, in the electronic text data 17 to be transmitted to the client side, and storing its contents in an electronic text data file 18; an input value generating function 15 automatically generating an input value before setting is made, for example, by the user in correspondence with the data item which is detected by the electronic text structure parsing function 11 and for which the data input is required, and giving the generated input value to the setting screen generating function 12; and an electronic text data reading function 16 reading the electronic text data including an input value which is previously set and stored in an electronic text data file 18, and giving the read data to the setting screen generating function 12.

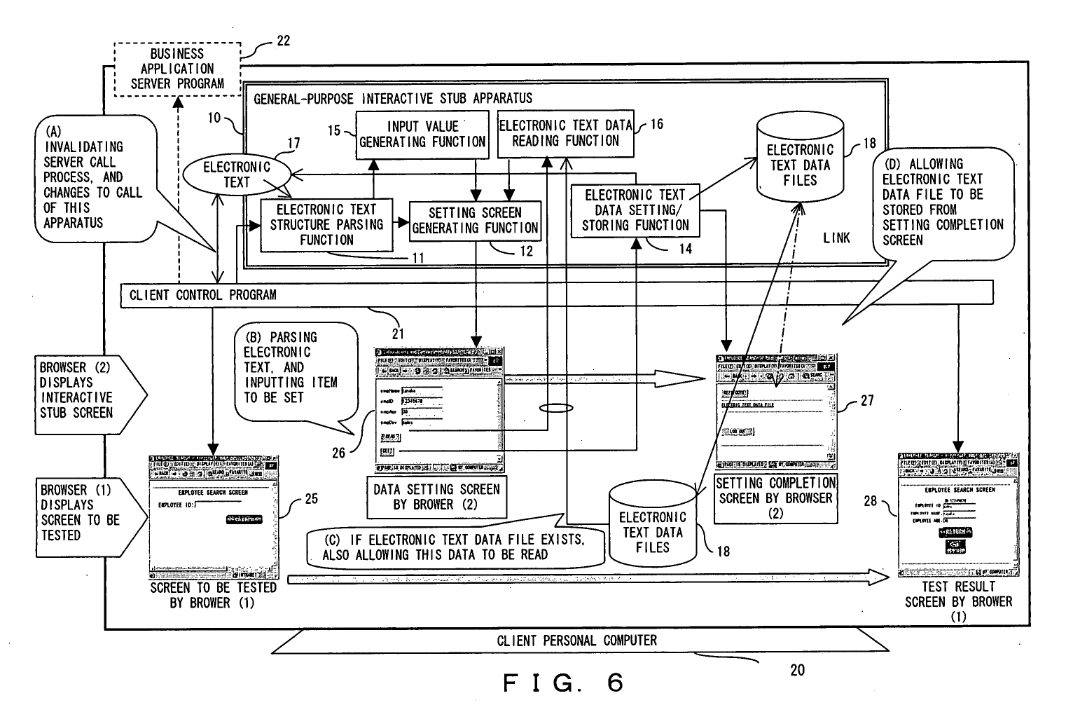

FIG. 6 shows the configuration of the entire system in the case where the general-purpose interactive stub apparatus is included in a client personal computer. In this figure, a client control program 21 is included in the client personal computer 20 along with the general-purpose interactive stub apparatus 10. The client control program 21 not only performs a control on a client side, but also executes a process between the client side and a business application server program 22 on the partner side as a client/server system. In this preferred embodiment, the client control program 21 is tested by using the general-purpose interactive stub apparatus 10, because the server program 22 is not yet completed.

In FIG. 6, in (A), a server reading process is invalidated, and changed to reading of the stub apparatus 10, so that the stub apparatus 10 is read out. Prior to this operation, a screen to be tested 25 is displayed on a screen of the client personal computer 20 by a browser (1). On the side of the general-purpose interactive stub apparatus 10, an electronic text transmitted form the client control program 21 is parsed in (B), an input screen on which data settings are required is displayed by a browser (2), and this becomes a data setting screen 26.

On the data setting screen 26, data is input, for example, from a user. However, required data can be also read from an electronic text data file 18 in (C). Upon termination of the data settings, a setting completion screen 27 is displayed by the browser (2), and at the same time, a test result screen 28 is displayed on the side of the browser (1). Note that the set data can be also stored in an electronic text data file 18 from the setting completion screen 27 of the browser (2)

In FIG. 6, the stub apparatus 10 can be included in the client personal computer 20. However, a screen display control program on the client side is included, for example, in a Web server, and the stub apparatus 10 can be included in an application server along with the client control program 21.

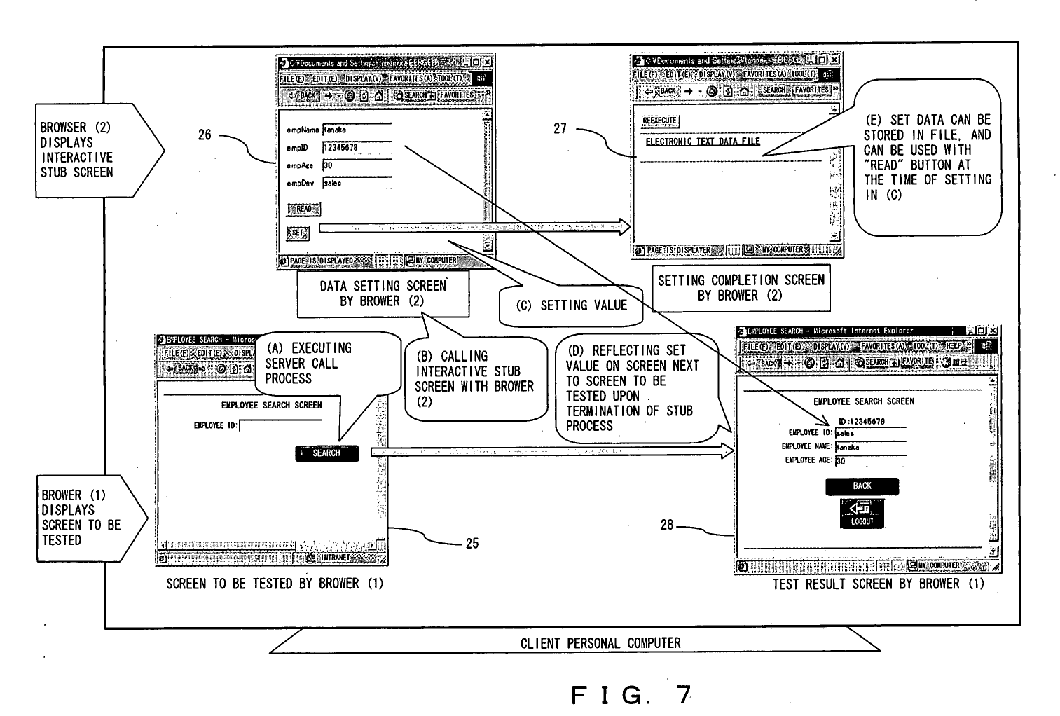

FIG. 7 explains a user view of the general-purpose interactive stub apparatus. A user presses a search button on the screen to be tested 25, which is displayed by the browser (1), on the screen of the client personal computer 20, whereby the server call process in (A) is executed, the data setting screen 26 as an interactive stub screen is displayed by the browser (2) in (B), and the user inputs a value on the data setting screen 26 in (C).

The user presses, for example, a set button on the data setting screen 26, so that the setting completion screen 27 is displayed on the browser (2), and the test result screen 28 on which the set value is reflected is displayed by the browser (1) in (D). Data set on the setting completion screen 27 is stored in an electronic text data file 18 with the press of a read button on the data setting screen 26.

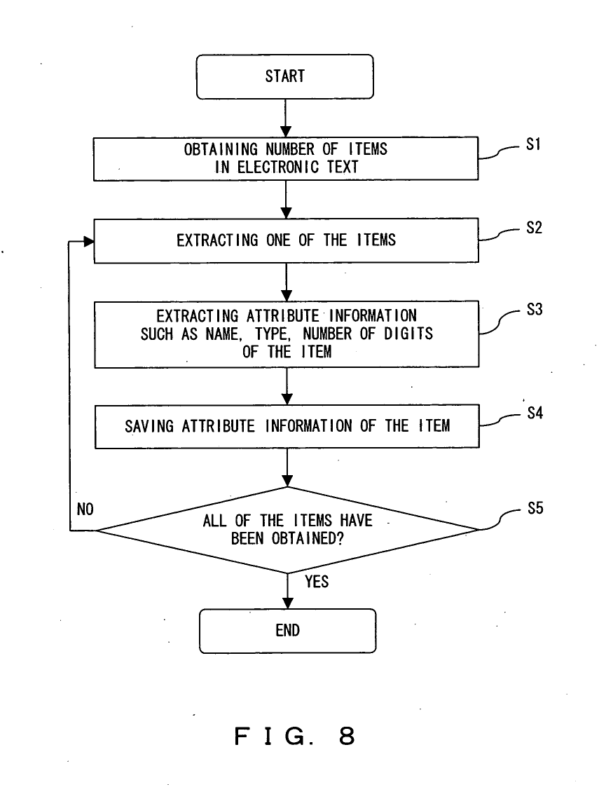

The processes executed in this preferred embodiment are described next with reference to the flowcharts shown in FIGS. 8 to 12. FIG. 8 is a flowchart showing the process executed by the electronic text structure parsing function.

Once the process is started in FIG. 8, the number of items for which a data input is required in an electronic text transmitted from the client program side is obtained in step S1. In step S2, one of the items is extracted. In step S3, attribute information such as the name, the type, the number of digits (length), the format, etc. of the extracted data item are extracted. In step S4, these items of the attribute information are saved in a working memory not shown, or the like. In step S5, it is determined whether or not the process has been terminated for all of the items. If the process has not been terminated yet, the operations in and after step S2 are repeated, and the process is terminated when the process is determined to have been terminated for all of the items.

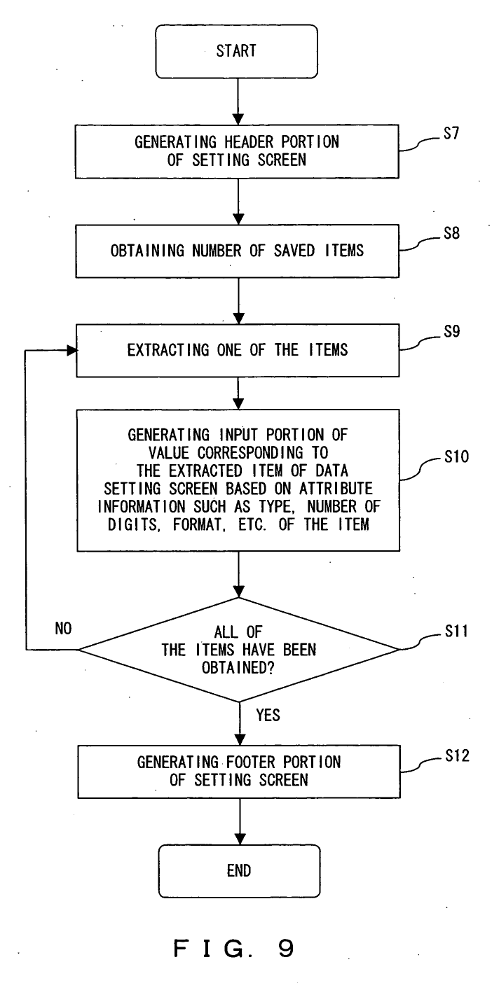

FIG. 9 is a flowchart showing the process executed by the setting screen generating function. Once the process is started in this figure, a header portion of the setting screen is generated in step S7. This header position is required to display the setting screen. In step S8, the number of items saved in the working memory, or the like is obtained in step S8. Then, in step S9, one of the items is extracted. In step S10, an input field of a value of the extracted item is generated on the setting screen based on attribute information such as the type, the number of digits, the format, etc. of that item. In step S11, it is determined whether or not all of the items have been obtained. If all of the items have not been obtained yet, the operations in and after step S9 are repeated. When all of the items are determined to have been obtained, a footer portion of the setting screen is generated in step S12, and the process is terminated.

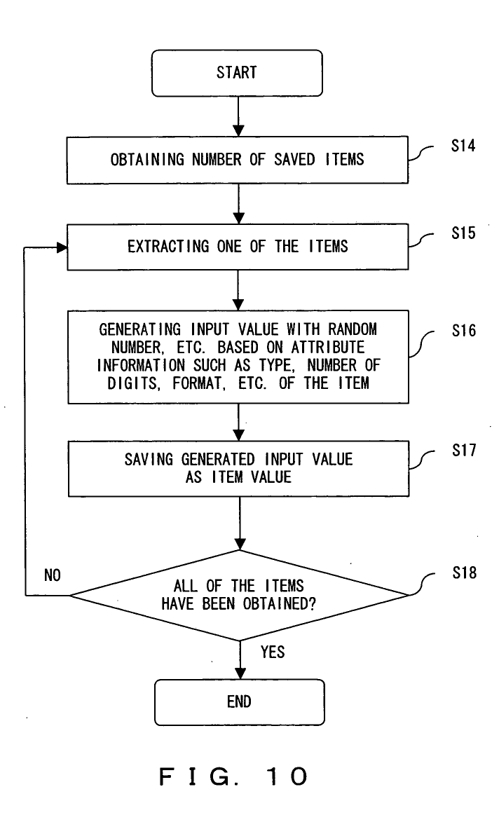

FIG. 10 is a flowchart showing the process executed by the input value generating function. The input value generating function 15 generates an input value beforehand as occasion demands, and gives the generated input value to the setting screen generating function 12 before the setting screen 13 for a data input is generated by the setting screen generating function 12 shown in FIG. 5, and a data value is input, for example, by a user.

Once the process is started in FIG. 10, the number of items saved in the working memory, or the like is obtained in step S14. In step 15, one of the items is extracted. In step S16, an input value is generated by using a random number, etc. based on attribute information such as the type, the number of digits, the format, etc. of the extracted item. In step S17, the generated input value is saved in the working memory, or the like as a value of the item. In step S18, it is determined whether or not all of the items have been obtained. If all of the items have not been obtained yet, the operations in and after step S15 are repeated. When all of the items are determined to have been obtained, the process is terminated.

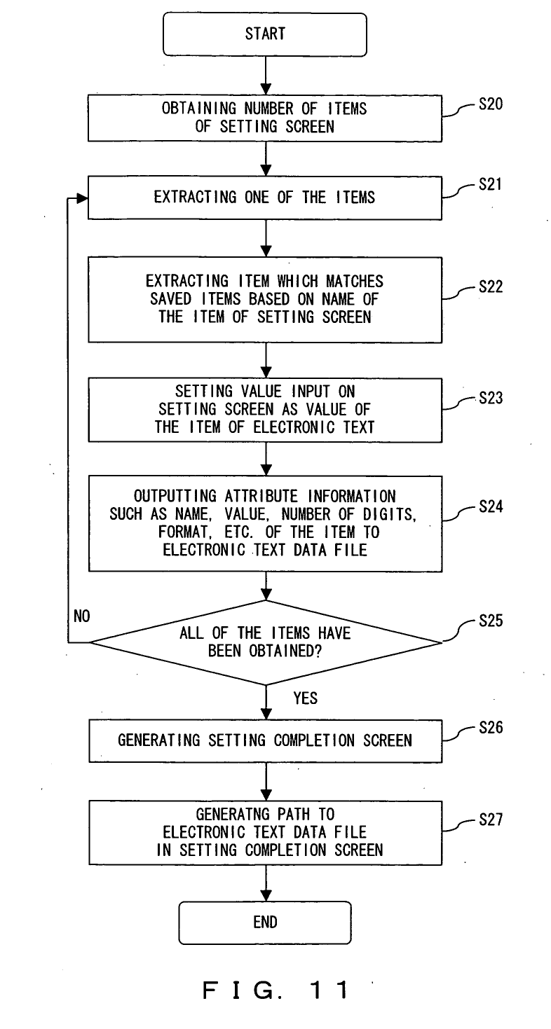

FIG. 11 is a flowchart showing the process executed by the electronic text data setting/storing function. Once the process is started in this figure, the number of data items which are displayed on the setting screen and for which a value input is required is obtained in step S20. In step S21, one of the items is extracted. In step S22, a matching item among items saved in the working memory, or the like is extracted based on the name of the item on the setting screen. In step S23, a value input from the user, etc. on the setting screen is set as a value of the item in an electronic text to be transmitted to the client side. In step S24, attribute information including that value is output to an electronic text data file 18 in addition to the name, the type, the number of digits, and the format of the item. In step S25, it is determined whether or not all of the items have been obtained.

If all of the items have not been obtained yet, the operations in and after step S21 are repeated. If all of the items have been obtained, the setting completion screen 27, which is described with reference to FIGS. 6 and 7, is generated and displayed in step S26. In step S27, a link (path) to the electronic text data file is generated on the setting completion screen 27, and the process is terminated.

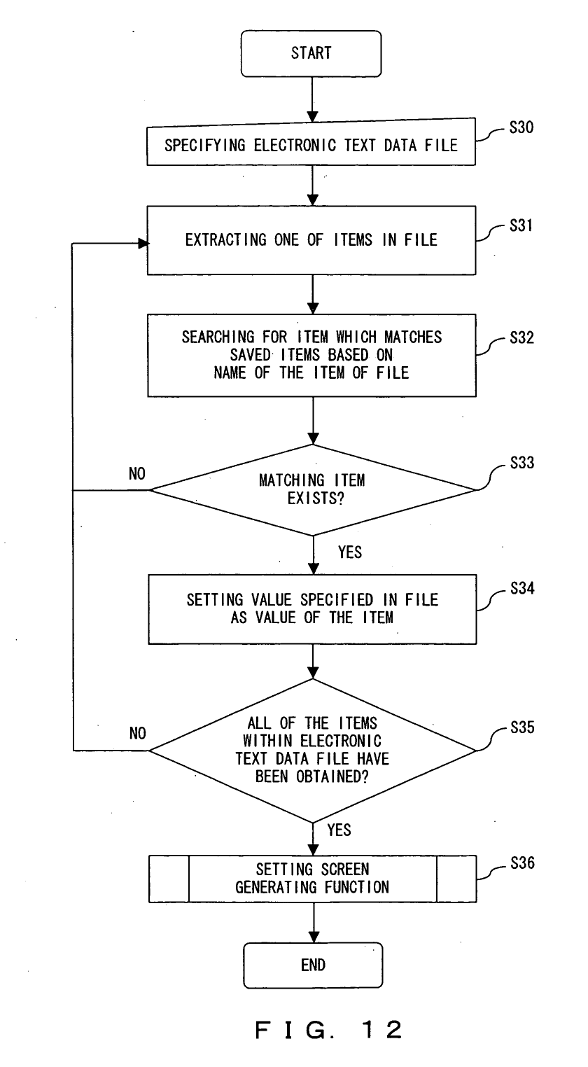

FIG. 12 is a flowchart showing the process executed by the electronic text data reading function. When the similar test is repeated, the electronic text data reading function 16 reads a value of input data at the time of execution of a previous test, which is stored in an electronic text data file 18, and gives the read value to the setting screen generating function 12.

Once the process is started in FIG. 12, a file among electronic text data files 18 is specified in step S30. An electronic text data file 18 stores, for example, data that corresponds to one test as one file. Target data can be read, for example, by specifying the name of a file.

In step S31, one of items within the file is extracted. In step S32, a matching item among items saved in the working memory is searched based on the name of the item within the file. In step S33, it is determined whether or not the matching item exists. If the matching item does not exist, the operations in and after step S31 are repeated. Here, the reason why the matching item is searched is that there is no need to read data for an item that is not used in the current test among the data items of the previous test stored in the file.

If the matching item is determined to exist in step S33, a process for setting the value stored in the file as the value of that data item is executed in step S34. In step S35, it is determined whether or not all of the items stored in the electronic data file have been obtained. If all of the items have not been obtained yet, the operations in and after step S31 are repeated. If all of the items have been obtained, the setting screen generating function is called in step S36, and the process is terminated.

The reason why the setting screen generating function is called in step S36 is to display the value of data, which is read from the electronic text data file 18, on the data setting screen. To set the value in the electronic text data to be transmitted to the client program side, it is sufficient to save the read value in the working area, and to set its value in the electronic text data. However, such operations do not notify a user that the test is run with which data. Therefore, the data must be displayed on the setting screen in order to notify the user of that data.

For example, the input value generated by the input value generating function 15 is given not directly to the electronic text data setting/storing function 14, but to the setting screen generating function 12 due to the same reason, namely, in order to notify the user of the input value.

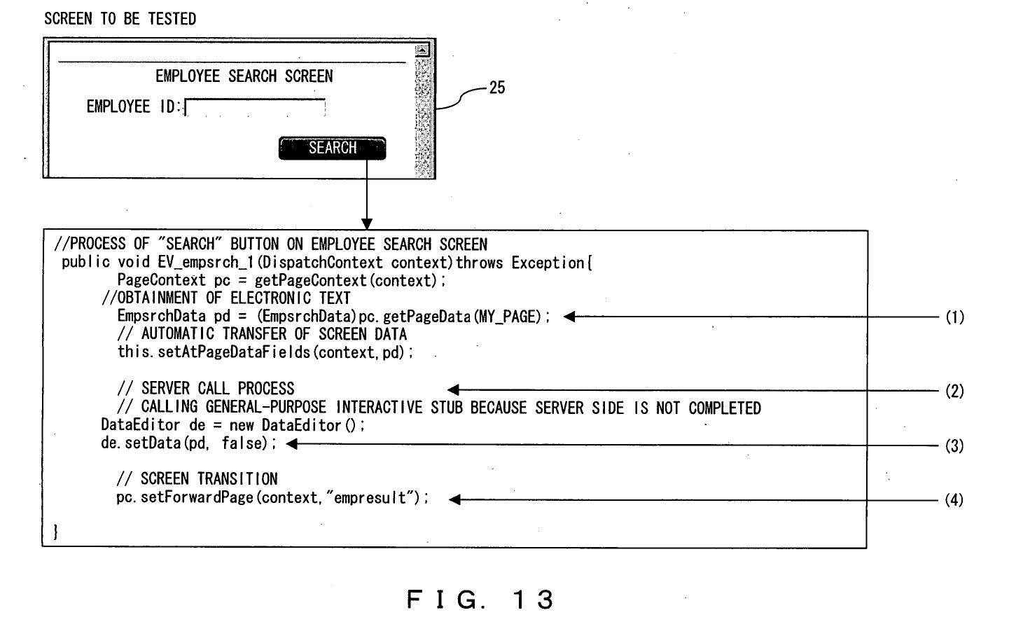

The processes executed in this preferred embodiment are further described by using specific examples with reference to FIGS. 13 to 19. FIG. 13 shows a description example of a general-purpose interactive stub apparatus call.

If the server side program is already completed, the process for reading the server side is executed in (2). Alternatively, the process for calling the stub apparatus is described. Here, assume that the client program is created with a Java (registered trademark) language, and the general-purpose interactive stub is implemented as a Data Editor class.

In FIG. 13, firstly in (1), an instance pd of an Empsrch Data class, which becomes an electronic text to the server, is obtained, an electronic text pd is then passed to the general-purpose interactive stub in (3), and the process is called. The second argument “false” indicates that the input value generating function is not used.

This program is executed, and the execution of this program stays in (3) until control is passed to the general-purpose interactive stub in (3), data is set on the data setting screen, and the setting completion screen is displayed. A screen transition process in (4) is executed at the same time the setting completion screen is displayed, so that a test result screen 28 is displayed.

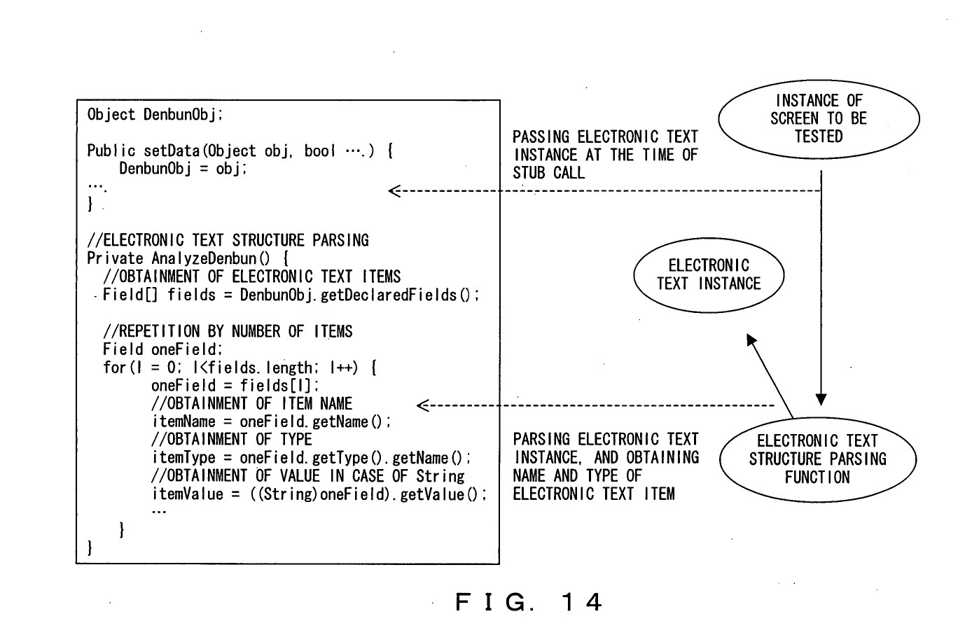

FIG. 14 explains an example of parsing made by the electronic text structure parsing function. This figure shows an example of the parsing of an electronic text written in a Java (registered trademark) language. In this figure, an electronic text instance is passed by an instance of the screen to be tested 25 when a stub is called, the electronic text structure parsing function 11 parses this electronic text instance, and obtains the names, the types, etc. of items within the electronic text. Namely, all of the items of the electronic text are obtained as an electronic text structure parsing process, and the name and the type of an item, and its value, etc. depending on need are repeatedly obtained by the number of the items.

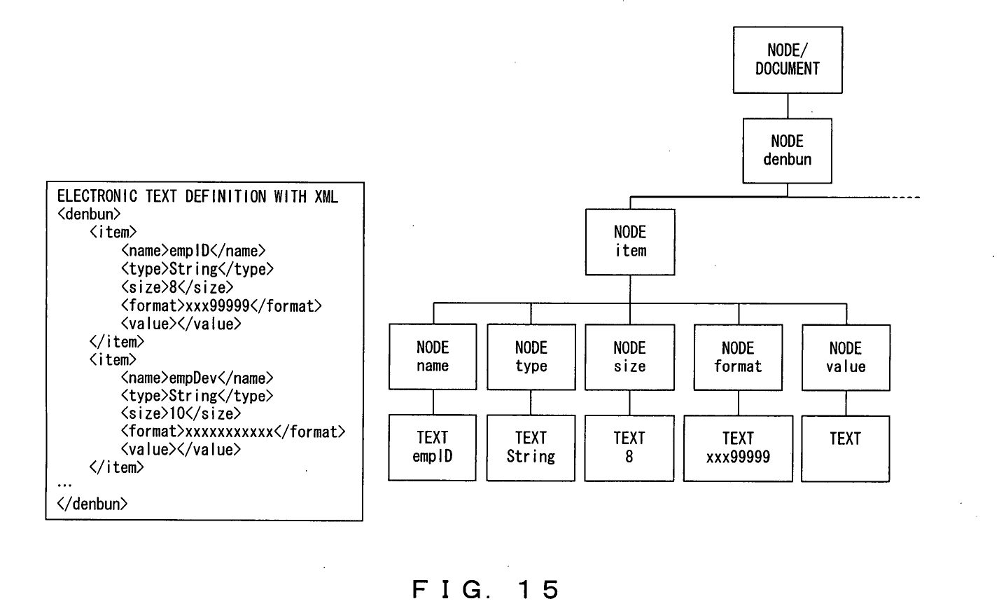

FIG. 15 shows an example of parsing of an electronic text written in an XML language, which is made by the electronic text structure parsing function. An electronic text received from the client program side is parsed by a DOM (Document Object Model) parser, the number of item nodes is extracted from a denbun (electronic text) node, and a text value of each node is obtained for a name node, a type node, a size (the number of digits) node, a format node, and a value node. For specific parsing, by way of example, Java API (Application Program Interface) for XML processing is used.

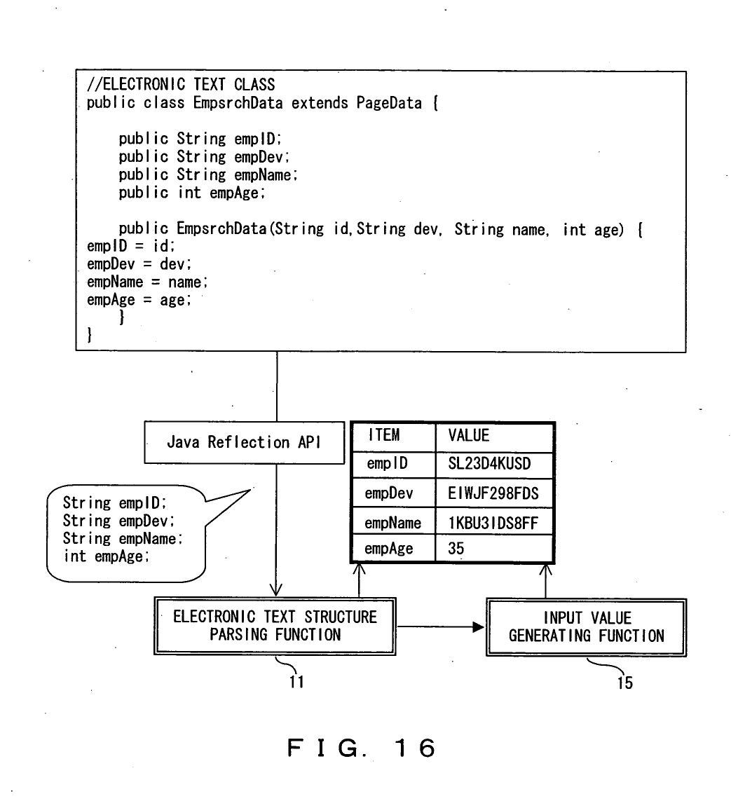

FIG. 16 shows a specific example of the processes executed by the electronic text structure parsing function and the input value generating function. In this example, an electronic text is implemented as a class of Java (registered trademark), and the name, the type, etc. of each item within the electronic text are obtained by using the Java reflection API. If the input value generating function 15 is used, a suitable value is generated, for example, by using a random number according to the type of each item, and the generated value is set as an input value.

In FIG. 16, names such as empID, etc., which correspond to items in the lower table, are obtained by the electronic text structure parsing function 11, and values such as SL23D4KUSD, etc. are generated by the input value generating function 15.

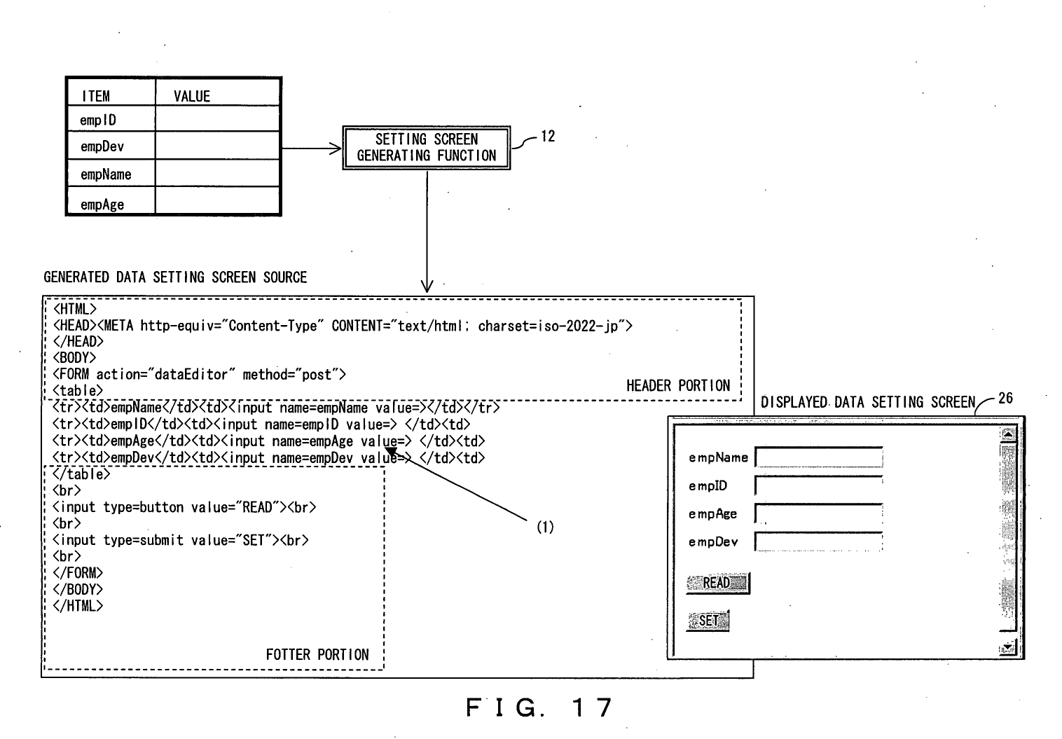

FIG. 17 explains an example of operations of the setting screen generating function 12. In this example, the setting screen is generated in a format of an HTML source. The HTML source for the setting screen is generated based on the names, the types, and the values of items obtained by the electronic text structure parsing function 11.

If the input value generating function 15 is used, for example, a portion of (1) becomes as follows.
<input name=empAge value=35>
   The value generated by the input value generating function 15 is displayed as a set value and as an initial value at the time of a display of the screen.

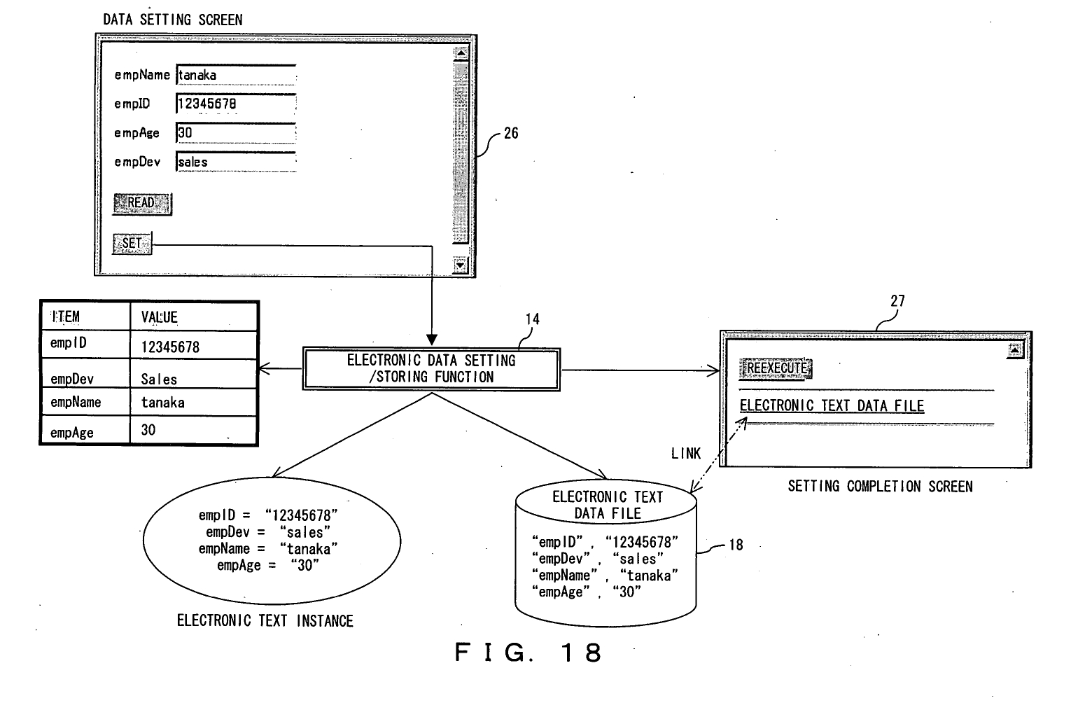

FIG. 18 shows an example of operations of the electronic text data setting/storing function 14. When a value is input by a user on the data setting screen 26, the electronic text data setting/storing function 14 extracts that value, and sets the value in an electronic text to be passed to the client side after once holding the value, for example, in an internal working memory. Additionally, the electronic text data setting/storing function 14 creates an electronic text data file 18. Here, the electronic text data file 18 is created as a CSV (Comma Separated Value) file.

Upon termination of these operations, the setting completion screen 27 is generated and displayed. In the setting completion screen 27, a link to the created electronic text data file 18 is embedded. With the click of the link, a user can store the file, for example, on a hard disk of a personal computer. Additionally, a reexecute button on the setting completion screen 27 is intended to call the data setting screen when the stub is again called.

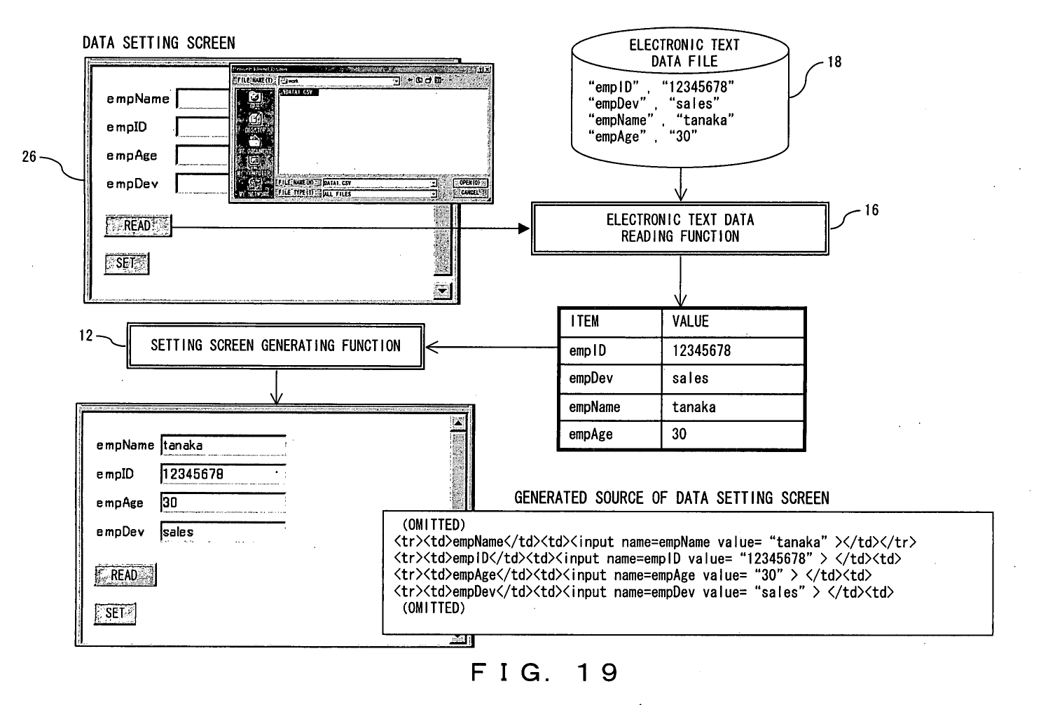

FIG. 19 explains an example of operations of the electronic text data reading function 16. In this figure, a read button is pressed on the data setting screen 26, so that a target electronic text data file is specified, the electronic text data reading function 16 is activated, and read data is given to the setting screen generating function 12 and displayed as an initial value of data on a generated screen.

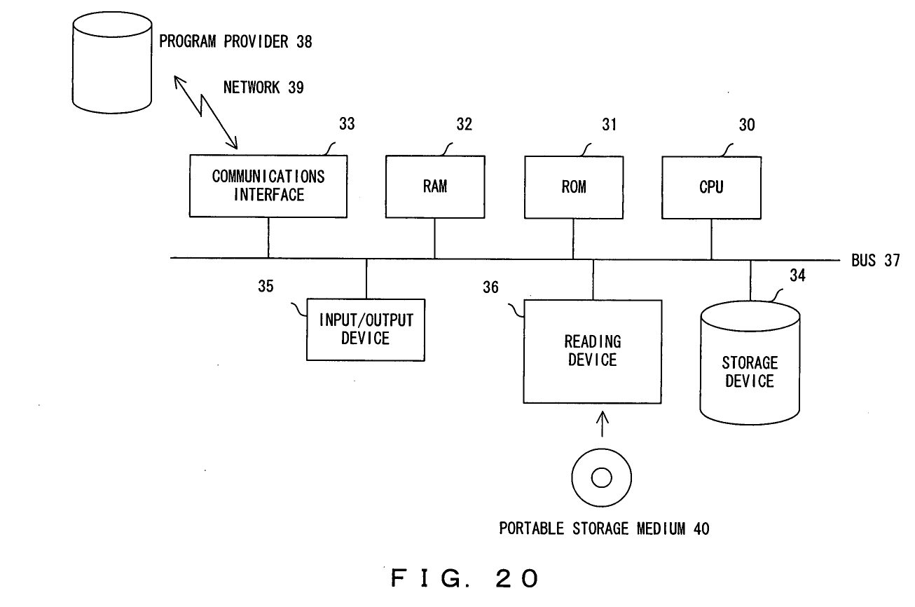

Up to this point, the details of the interactive stub apparatus for testing a program according to the present invention are described. This stub apparatus can be configured as a general computer system as a matter of course. FIG. 20 is a block diagram showing the configuration of such a computer system, namely, the hardware environment.

In FIG. 20, the computer system is configured by a central processing unit (CPU) 30, a read only memory (ROM) 31, a random access memory (RAM) 32, a communications interface 33, a storage device 34, an input/output device 35, a reading device 36 of a portable storage medium, and a bus 37 to which all of the above described constituent elements are connected.

As the storage device 34, various types of storage devices such as a hard disk, a magnetic disk, etc. are available. The program which is represented by the flowcharts shown in FIGS. 8 to 12, and the like are stored in such a storage device 34 or ROM 31, and such a program is executed by the CPU 30, whereby the test of the client side program, etc. in the preferred embodiment can be implemented.

Such a program can be stored from a side of a program provider 38, for example, in the storage device 34 via a network 39 and the communications interface 33, or can be stored onto a marketed and distributed portable storage medium 40. The program is then set in the reading device 36, and executed by the CPU 30. As the portable storage medium 40, various types of storage media such as a CD-ROM, a flexible disk, an optical disk, a magneto-optical disk, a DVD, etc. are available. The program stored on such a storage medium is read by the reading device 36, whereby the test of the program in the preferred embodiment can be run.

As described above in detail, according to the present invention, the need for creating a stub program, which corresponds to a program, etc. each time a test of the program is run is eliminated, whereby stub creation for the test, which is a useless operation, can be eliminated. Additionally, useless operations such as compilation, etc. can be omitted unlike a conventional method directly describing data in a program source. Also source parsing becomes unnecessary, so that the reliability of a test is improved because parsing errors do not occur.

Still further, data creation and test running can be made simultaneously with an interactive process for setting a data value from a screen, whereby the efficiency of test operations can be increased. Still further, a data value input made, for example, by a user is saved in correspondence with each test, whereby the value can be reused when a test of a similar program type is run, and the efficiency of the test is improved. This greatly contributes to an increase in the efficiency of a program test.

1. An interactive stub apparatus for testing a program for executing a process with externally given data, comprising:
an electronic text parsing unit parsing an electronic text transmitted from a program to be tested to detect a required data item; and
an electronic text data setting unit embedding an input data value, which corresponds to the detected data item, in an electronic text to be transmitted to a side of the program to be tested.

2. The interactive stub apparatus for testing a program according to claim 1, further comprising
a setting screen generating unit generating a data setting screen for receiving the input data value, which corresponds to the detected data item, and giving the set value to said electronic text data setting unit.

3. The interactive stub apparatus for testing a program according to claim 2, further comprising
an input value generating unit automatically generating input data in correspondence with the data item detected by said electronic text parsing unit, and giving the generated input data to said setting screen generating unit.

4. The interactive stub apparatus for testing a program according to claim 2, further comprising:
an electronic text data storing unit storing the set data value embedded by said electronic text data setting unit; and
an electronic text data reading unit reading the data stored in said electronic text data storing unit, and giving the read data to said setting screen generating unit as the input data.

5. A computer-readable portable storage medium, which is used by a computer for testing a program for executing a process with externally given data and on which is recorded a stub program for causing the computer to execute a process, the process comprising:
parsing an electronic text transmitted from a program to be tested to detect a required data item; and
embedding an input data value, which corresponds to the detected data item, in an electronic text to be transmitted to a side of the program to be tested.

6. The computer-readable portable storage medium according to claim 5, the process further comprising
a setting screen generating process of generating a data setting screen for receiving the input data value, which corresponds to the detected data item, and giving a set value to said step of embedding the input data value, as the input data value.

7. The computer-readable portable storage medium according to claim 6, the process further comprising
an input value generating process of automatically generating input data, which corresponds to the detected data item, and giving the generated input data to said setting screen generating step.

8. The computer-readable portable storage medium according to claim 6, the process further comprising:
storing the set data value embedded in the electronic text to be transmitted to the side of the program to be tested; and
reading the stored set data from the electronic text data, and giving the read data to said setting screen generating step as the input data.

9. A stub program, which is used by a computer for testing a program for executing a process with externally given data, and causes the computer to perform:
parsing an electronic text transmitted from a program to be tested to detect a required data item; and
embedding an input data value, which corresponds to the detected data item, in an electronic text to be transmitted to a side of the program to be tested.

10. A method testing a program for executing a process with externally given data, comprising:
parsing an electronic text transmitted from a program to be tested to detect a required data item; and
embedding an input data value, which corresponds to the detected data item, in an electronic text to be transmitted to a side of the program to be tested.

11. A stub apparatus for testing a program for executing a process with externally given data, comprising:
electronic text parsing means for parsing an electronic text transmitted from a program to be tested to detect a required data item; and
electronic text data setting means for embedding an input data value, which corresponds to the detected data item, in an electronic text to be transmitted to a side of the program to be tested.
